(19) United States
(12) Patent Application Publication
(10) Pub. No.: US 2004/0026694 A1
(43) Pub. Date: Feb. 12, 2004

(54) Storage device, especially for the intermediate storage of test wafers

(76) Inventors: Jakob Blattner, Ermatingen (CH); Rudy Federici, Berg (CH)

Correspondence Address: VENABLE, BAETJER, HOWARD AND CIVILETTI, LLP, P.O. BOX 34385, WASHINGTON, DC, 20043-9998, US

(21) Appl. No.: 10/332,459

(22) PCT Filed: Jul. 6, 2001
(86) PCT No.: PCT/CH01/00422

(30) Foreign Application Priority Data
Jul. 9, 2000 (CH) 135300

(51) Int. Cl. H01L 23/58

(52) U.S. Cl. 257/48

(57) ABSTRACT

The invention relates to a storage device for the intermediate storage of articles such as substrates, wafers, especially test wafers, and the like, used in the production of semiconductor elements. The aim of the invention is to provide a corresponding device with which said articles can be assembled in a stack or a batch in an efficient manner while meeting the strict requirements made on clean room conditions. To this end, the storage device is provided with a housing that includes an inner chamber in which, in a loading/unloading zone, a device for introducing the articles into and removing them from the housing is provided. At least one closable opening is provided on said housing through which the articles are introduced and removed, as well as a first handling device for handling the articles in the loading/unloading zone. The articles can be arranged in the inner chamber in open transportable storage means, such as magazines, the inner chamber disposing of storage locations for the storage means. The storage device is further provided with a transfer device for producing stacks of articles. A transport box for articles can be positioned with its open side on the at least one opening (6) of the housing (2). One or more articles are directly gripped by means of the first handling device and are introduced into the inner chamber. The articles are inserted in one of the plurality of storage means (25) that are already arranged within the inner chamber. The storage means (25) can be arranged in the storage locations (43) of the inner chamber by means of a second handling devices. The transfer device is also provided within the inner chamber and is used to produce a stack of articles from one or more articles withdrawn from at least one storage means (25) and to insert a receiver arranged in the inner chamber.

The invention relates to a storage device for the intermediate storage of articles such as substrates, wafers, especially test wafers, and the like, provided for the production of semiconductor elements, wherein the storage device has a housing which includes an inner chamber in which, in a loading/unloading zone, there is provided a device for introducing the articles into and removing them from the housing, for which purpose at least one closable opening is provided on said housing through which the articles are introduced and removed, there is also provided a first handling device by means of which the articles can be handled in the loading/unloading zone, the articles can be arranged in the inner chamber in open transportable storage means, such as magazines, for example, wherein the inner chamber has storage locations for the storage means, and the storage device also has a transfer device for producing stacks of articles. The invention also relates to a method according to the preamble of claim 12.

Substrates pre-treated in a specific fashion, such as semiconductor disks, glass plates or the like, form the basis for the manufacture of electronic components. Semiconductor disks, especially silicon disks, are usually described as wafers in this context. For the production of electronic components these substrates must pass through various process stages for their surface treatment. In this case, raw wafers (unprocessed wafers) are produced, for example, and are generally placed in intermediate storage in transport and storage containers between passage through various process stages. In order that the individual process stages yield good working results, it is frequently necessary to set process parameters. In many cases, the process parameters are determined empirically by first subjecting so-called test wafers to the treatment process. The values of the parameters to be set can then be derived with reference to their state after one or several runs through the particular process.

Both test wafers and wafers actually to be processed must be inserted as wafer stacks into a transport container for transport to the actual treatment process. The number of wafers provided in a container is called a “batch” (stack). The batch size is standardised and is usually 25 (or 13) wafers. For the processing itself the wafers must be removed from the transport container, supplied to an apparatus for performing the treatment process and then placed back in a container again.

A basic problem with the complete processing and intermediate storage is that the substrates must be kept away from impurities and dirt. Even the smallest impurities as a result of dust or other particles produce some damage to the corresponding area of the substrate surface. This can lead to appreciable part reject rates of the end products manufactured from these substrates. Hence the processing usually takes place in so-called clean-room conditions, i.e. the processing zones must exhibit a certain, stipulated purity in relation to these contaminant particles. The same also applies to the intermediate storage, i.e., the storage containers.

Thus, storage devices for the intermediate storage of wafers have already been disclosed, for example, in DE 198 47 659, in which wafers are stored open. Devices for loading and unloading of transport containers with wafers are also provided in these storage devices. In addition, there is usually a freely movable robot arm with which individual wafers can be gripped and brought from their horizontally aligned storage means to the loading and unloading device. However, an unsatisfactory aspect of these already known storage devices is that the assembly of individual wafer stacks takes a relatively large amount of time. Furthermore, these storage devices require a relatively large amount of space in relation to their storage capacity. It is also only possible to clean the storage means at great expense which, however, should take place regularly.

International Patent Application WO 00/22653 further describes a sorting/storage device for wafers which can provide intermediate storage for wafers arranged in cassettes in one part of the installation and can also assemble wafer stacks. For this purpose the wafers are arranged in the sorting/storage device in standard transport boxes designed as FOUPs (Front Open Unified Pods). The FOUPs are opened at a lock and then introduced completely into a first chamber of the installation housing. Here, the complete transport box can either be placed in intermediate storage in a stocker or brought to a closable interface. The closable interface separates the first chamber from a second chamber of the housing, wherein in the second chamber there are located various measuring and reading devices as well as a robot with which the wafer stack can be assembled. The wafer stacks to be supplied from the installation are produced by always inserting individual wafers directly into a FOUP using the robot. The FOUP can then be withdrawn from the installation or placed in intermediate storage in the stocker. This already known installation is also unsatisfactory in terms of the space requirement of the installation and the expenditure required to achieve good clean-room quality.

The object of the invention is thus to provide a storage device for such articles in which it is additionally possible to assemble a stack or a batch of the articles in an efficient fashion while meeting the strict requirements made on clean-room conditions.

This object is achieved by a storage device of the type specified initially according to the invention whereby a transport box for articles can be positioned with its open side on the at least one opening of the housing, one or a plurality of articles are directly gripped by means of the first handling device and are introduced from the transport box into the inner chamber, the articles can be inserted in one of the plurality of storage means already arranged within the inner chamber, the storage means can be arranged in storage locations of the inner chamber by means of a second handling device and the transfer device is also provided within the inner chamber, with which one or a plurality of articles can be withdrawn from at least one storage means to assemble an article stack and can be inserted in a receiver arranged in the inner chamber.

It is thus provided according to the invention that the transport boxes are not introduced into the multifunctional storage device. Since there is the risk that the transport boxes may be contaminated with particles on their outer surfaces, the expenditure for maintaining specific clean-room qualities in the storage device itself can hereby be kept comparatively low. Despite this low expenditure, the risk of articles being contaminated can be kept low.

Storage means are provided so that the wafers or substrates removed from a transport box can be placed in intermediate storage in the storage device, preferably in batches. These storage means, preferably open magazines, are transportable to transport the wafers inside the storage device itself but should usually remain in the storage device even if the wafers so far arranged therein are withdrawn from the storage device. The risk of any contamination of the wafers is hereby further reduced.

Compared with the individual handling of each wafer, by means of the simultaneous transport of several wafers in one storage means, the wafers required to form a wafer stack can be brought more quickly to the loading and unloading device. In addition, only one storage means needs to be transported and handled by the gripper. Since the wafers can remain in the storage means during the transport to the transfer device or to the loading/unloading zone, the risk of any damage to the wafer, for example as a result of unloading, is considerably reduced.

Furthermore, it is now much easier to clean the storage means since these can, for example, be removed individually from the storage device and cleaned outside thereof. For this purpose, it is no longer necessary to shut down the complete storage device.

A further advantage of the storage device according to the invention is that the handling device for handling the articles can have a far simpler design than the robot disclosed in DE 198 47 659. In the storage device according to the invention only single storage means need to be gripped and transported by its handling device. With regard to possible damage to the wafer, this is far less critical than the direct handling of a wafer by a robot. In addition, only a relatively small number of storage locations need be approached by the handling device. Compared with said previously known storage device in which the robot must approach each individual compartment, this produces a lower design expenditure.

The handling device provided to transport the storage means can be constructed in various ways especially depending on the design configuration of the storage means. It must merely be ensured that the storage means are securely gripped. However, it is preferable if the handling device has a passive gripper. Such a gripper, for example, grips a storage means during a movement of an arm of the handling device and carries it along. A separate movement of the gripper itself is not necessary, unlike the case of a two-jaw gripper, for example, whose jaws make an in-feed movement.

The storage means can preferably be constructed in the form of open cassettes as are provided in a similar fashion in transport containers for wafers. These storage means have slots arranged parallel one next to the other, in which the wafers are inserted. The slots preferably run vertically so that the wafers are aligned with their two disk surfaces substantially parallel. The storage means is further provided with a base with which it can be placed on a storage surface, for example, of the storage locations, which runs substantially horizontally if possible.

In a preferred embodiment of the invention, the loading and unloading device has a single-wafer gripper with which wafers can be individually withdrawn from or inserted in the storage means. By using this gripper, logical units of wafers can be assembled fully automatically from wafers in intermediate storage. Thus, for example, it is possible to assemble a stack of test wafers, insert this in a storage means and likewise store this storage means fully automatically at one of the storage locations of the storage device until the stack is required for production. The wafer stacks can preferably be assembled at times during which the loading and unloading device has no other task to perform.

However, the wafer stack can also be assembled from a storage means which has been brought from a storage location to the loading and unloading device. Since the individual storage means can preferably receive more wafers than are present in a wafer stack to be inserted or withdrawn, the wafer stack can be assembled from the wafers of only one storage means. It is however possible to use several storage means for this purpose.

The storage device according to the invention is especially suited for the intermediate storage and stacking of test wafers. Naturally, wafers actually provided for the production of semiconductor components can also be stored in said device. Other substrates and also production means from the production of semiconductor elements can also be placed in intermediate storage.

Further preferred embodiments of the invention are obtained from the claims.

The invention is explained in detail with reference to the embodiments shown purely schematically in the drawings, wherein:

FIG. 1 is a perspective view of a storage device according to the invention in which an inherently completely closed front is shown partially open;

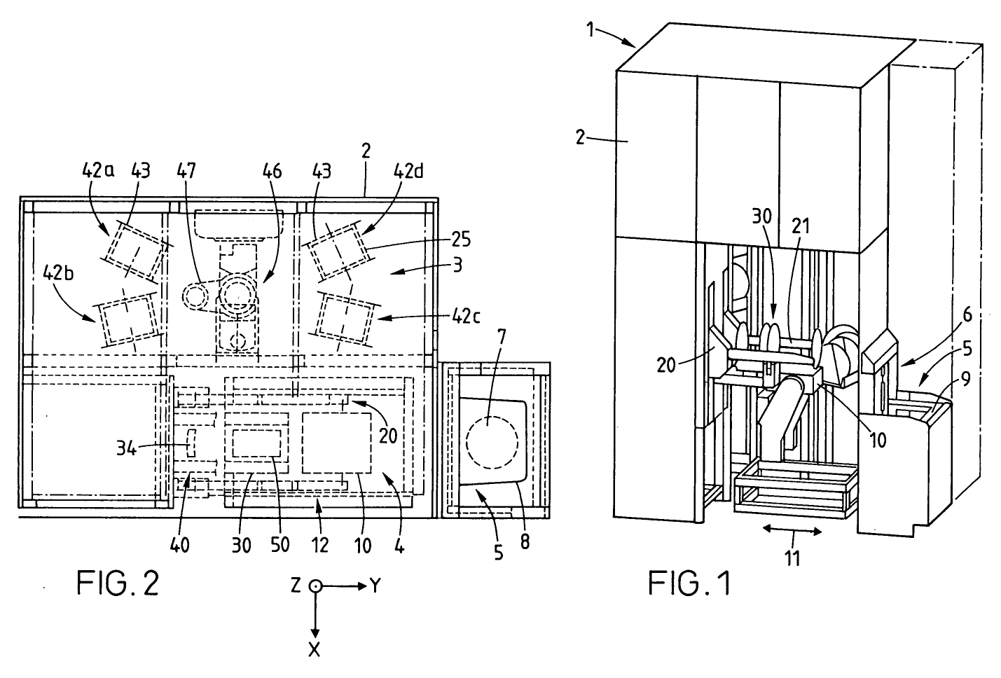

FIG. 2 is a top view of a storage device according to the invention;

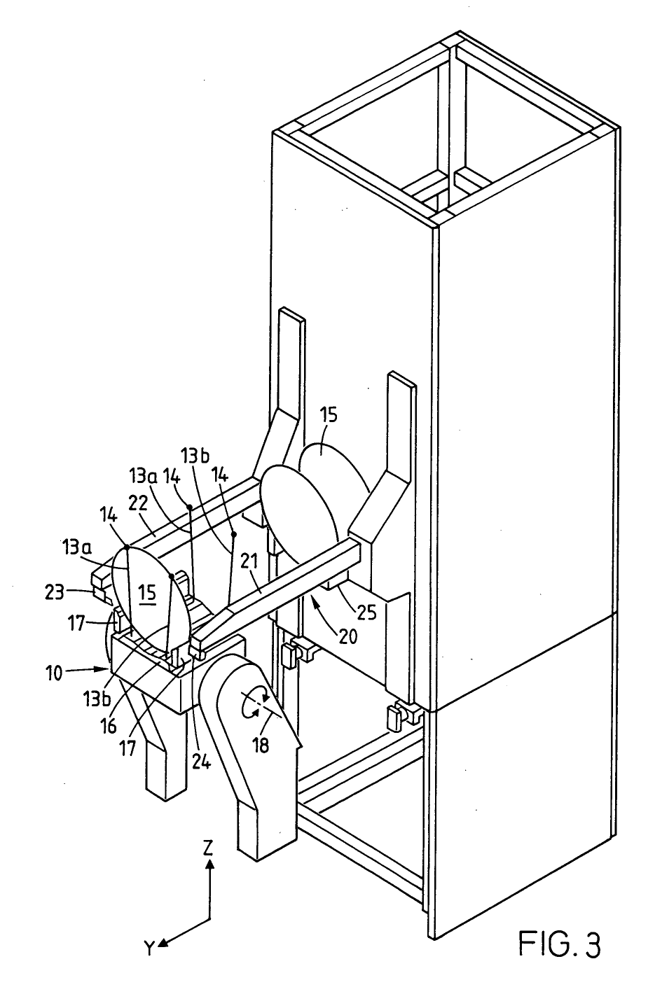

FIG. 3 is a part of a loading/unloading zone of the storage device from FIG. 1;

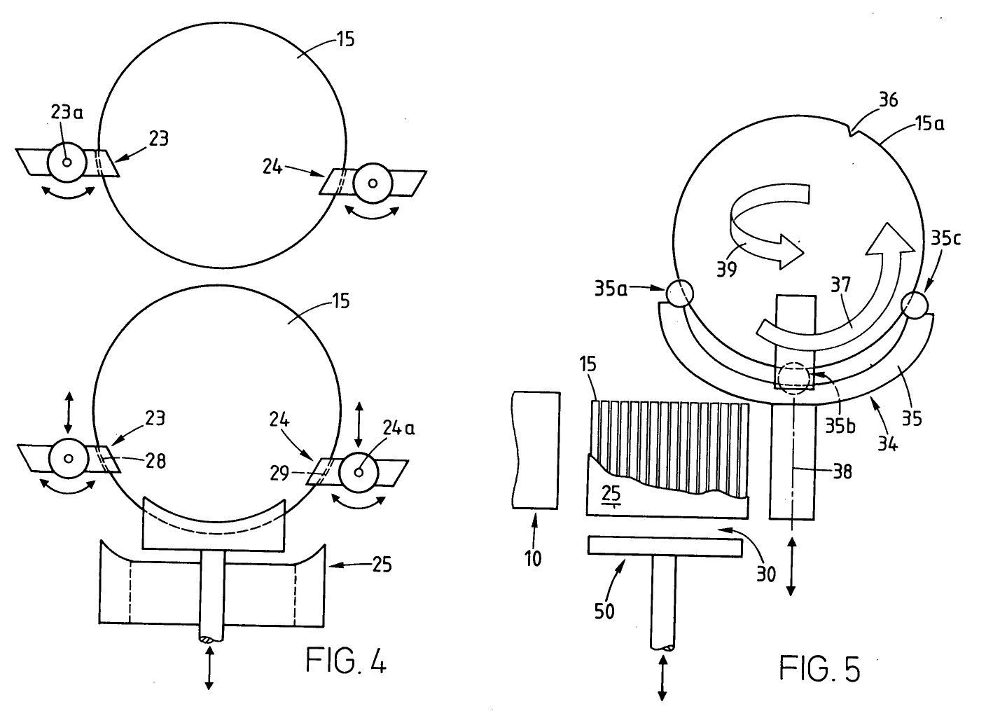

FIG. 4 is a front view of a gripping means of a transfer gripper;

FIG. 5 is a front view of a loading location and a detection device of the storage device;

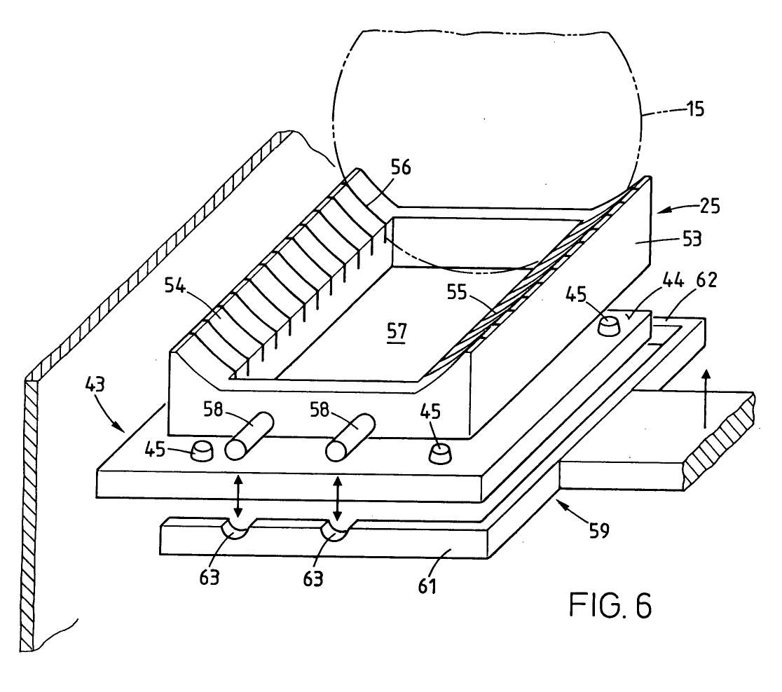

FIG. 6 is a perspective view of a storage means arranged above a storage location as well as a gripper element;

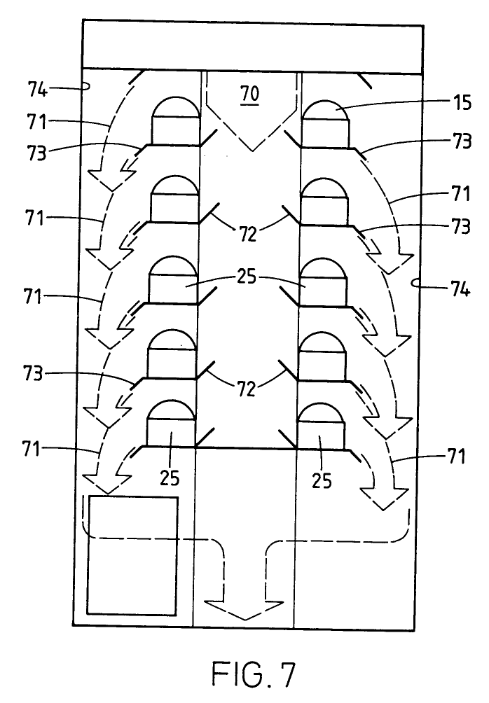

FIG. 7 is a front view of a storage area of the storage device from FIG. 1.

FIGS. 1 and 2 show a storage device 1 according to the invention whose closable housing 2 forms a single cohesive inner chamber. A storage zone 3, a loading/unloading zone 4 and a transfer zone 12 are provided in the inner chamber. In the zones downward-directed air flows are produced independently of one another and ensure clean-room conditions in the entire housing.

A loading/unloading station 5 is located in the vicinity of a closable opening 6 of the housing 2. The loading/unloading station 5 can be used to remove a wafer stack 7 shown only in FIG. 2 from a transport box 8 and insert it in the storage device 1. The loading/unloading station 5 can also be used to insert a wafer stack from the storage device 1 into the transport box 8. For this purpose a transport box 8 with its open side pointing towards the closable opening 6 can be positioned and opened on a positioning area 9 of the loading/unloading station 5 arranged outside the inner chamber. Such transport boxes have been known and standardised for some time, for example, as FOUP (Front Open Unified Pod) or SMIF boxes (Standard Mechanical Interface). Mechanisms for the simultaneous opening or closing or a transport box and a closure plate of an opening in the housing are thus familiar to the person skilled in the art.

In the loading/unloading zone located opposite the opening 6 in the housing 2 there is arranged a stack gripper 10 (so-called batch gripper) for gripping several wafers at the same time, preferably the total content of a transport container. The first handling device constructed as stack gripper 10 can be displaced along a translatory axis (double arrow 11) and has a gripper for every two wafers of a stack. As especially shown in FIG. 3, each gripper has two gripping heads 14 secured to rotatable rods. For reasons of clarity, FIG. 3 only shows the two outer grippers of the stack gripper 10. Between these two grippers shown there are a number of corresponding further grippers so that one gripper is present for every two wafers 15 of a wafer stack.

The stack gripper 10 also has a longitudinally displaceable counter-stay 16 and a receiving means having two strips 17 provided with slots. The wafers can thus be held between the counter-stay 16 and the gripping heads 14 with the gripper only contacting the wafer at its side edges. The wafers can also be put down in the two strips 17. The grippers are interconnected and always execute the same movements together. For removal of wafers arranged substantially horizontally in a FOUP box the stack gripper 10 is aligned with its rods 13a, 13b substantially horizontally. For the subsequent handling of the wafers the stack gripper 10 is swivelled through approximately 90° about an axis 18 so that the wafers have their surfaces vertically aligned. This situation is shown in FIG. 3. Such a stack gripper 10 is known, for example, from WO98/15971 by the same applicant. The contents of the disclosure of this application with respect to the design structure and the movement possibilities of the stack gripper are hereby taken up fully by reference.

In the transfer zone 12 directly adjacent to the loading/unloading zone 4 there is provided a further handling device constructed as a transfer gripper 20 with which wafers can be removed from the stack gripper. For this purpose the stack gripper 10 described previously remains at a predefined transfer point in the alignment in which the wafers are arranged in the receiving means and are substantially vertically oriented. For removal of the wafers by the transfer gripper 20 the gripping heads 14 of the stack gripper also release the wafers so that they can be removed from the stack gripper in a substantially vertically upward direction.

Such a transfer gripper 20 can, for example, be constructed in the same way as the gripper disclosed in WO 00/03417 by the same applicant. The contents of the disclosure of this older application are thus taken up fully with reference to the design configuration and the movement sequence of such a gripper. This transfer gripper 20 also shown in FIG. 3 has two simultaneously moveable arms 21, 22, at some distance from one another, having gripping means 23, 24 provided at their free ends. Only one wafer at a time can be gripped and handled jointly by the one ends of the slotted gripping means 23, 24 of the two arms. The distance between the two gripping means is smaller than the diameter of a wafer so that, as a result of an upward movement from below, one wafer can be gripped by the passive gripping means and can be removed from the stack gripper (FIG. 4). By means of a movement in the opposite direction a wafer can be placed in the stack gripper 10 or in a storage means 25.

As shown in FIG. 4, the gripping means 23, 24 can be constructed so that they can each swivel about an axis 23a, 24a aligned orthogonally with respect to the plane of the drawing. By this means it is possible to construct the transfer gripper 20 both as a single-wafer gripper and as a multiple gripper. By rotating through 180°, second gripping means 26, 27 lie opposite one another, on which several slotted receivers are constructed respectively one behind the other, for handling a plurality of wafers simultaneously. The individual receivers can be shaped substantially the same as those provided for the gripping means 23, 24 of the single-wafer gripper. By suitably selecting a spacing between successive receivers for wafers at the gripping means 26, 27 of the multiple gripper, either wafers 15 directly adjacent to one another can be gripped or, for example, only every second, third etc. wafer of the stack can be removed.

For this purpose, the receivers of the multiple or single-wafer grippers have a contact point 28, 29 on each side of a wafer stack, whose spacing is smaller than a wafer diameter. Without a wafer to grip, the contact points 28, 29 are always located below the wafer 15. Apart from a rectilinear movement along a storage means which is thereby possible (perpendicular to the plane of the drawing in FIG. 4), the single-wafer gripper can also be displaced parallel to the two surfaces of the wafer. By this means the single-wafer gripper can be transferred from a displacement position to a transport position. A wafer can hereby be gripped by the gripper and raised. The particular wafer is thereby fixed in a two-point position in the gripper and, without performing relative movements towards the gripper, is carried along by said gripper into the transport position in which the wafer is located completely outside the initial stack. From here the wafer can be moved by the transfer gripper to the receiving means and inserted therein. In this fashion the required wafers can be removed from the initial stack and assembled in the strips 17 of the receiving means to form a new wafer stack.

The transfer gripper can be provided with a sensor means not shown, for example, an optical light barrier sensor which can determine whether there is a wafer which can be gripped or has already been gripped between the two contact points. Provision can also be made for determining by means of suitable detection means whether wafers are correctly inserted in the storage means or receiving means.

Alternatively to the single-wafer gripper described here, a multiple gripper can also be used, comprising for example a plurality of single-wafer grippers described previously, as was also described in the older application CH 1999 1569/99 by the same applicant. With such a multiple gripper the individual grippers can be actuated individually but can only be displaced together along a wafer stack. With this multiple gripper arbitrary wafers can be removed from an initial stack and moved jointly to the receiving means and put down there. The contents of the disclosure of CH 1999 1569/99 are hereby completely taken up by reference with regard to the design structure of the transfer device and the handling method described therein.

Whatever the form in which the transfer gripper is constructed, it can in each case insert the wafers removed by it in a likewise vertical alignment into a storage means 25 shown only partly in FIG. 3, for example, a magazine or a cassette arranged behind the stack gripper 10. For this purpose the storage means 25 is arranged at a loading location 30 (FIGS. 1 and 2).

At the loading location there can be provided an ejector 50 (FIG. 5) which can be passed through a storage means 25 and thereby lifts all the wafers in the storage means upwards. The ejector can be a component shaped according to the storage means 25 explained hereinafter in further detail, whose width is smaller than an opening in the storage means 25. In addition, the ejector can be displaced in the vertical direction. The ejector 50 is also provided with slots to accommodate wafers wherein its slots have the same spacing as those of the storage means 25. By this means, as a result of a vertical upward movement of the ejector, the ejector 50 can be passed through a storage means 25 and a wafer stack can be transferred from the storage means to the ejector. By means of a corresponding downward movement, a stack can be inserted in a storage means.

A detection station 40, shown only schematically in FIG. 2, into which the transfer gripper 20 can also insert wafers, can also be arranged behind the storage means in a line with the stack gripper 10 and the loading location 30. The range of the transfer gripper 20 which is movable only along the two translatory axes Y and Z thus extends from the detection station 40 to the stack gripper 10.

As can be seen from FIG. 5, the detection station 40 has a vertically displaceable slider 34 which can lift a single wafer or a plurality of wafers 15a upwards at the same time using a slider arm 35. The wafer 15a in this case rests on three or more contact points 35a, 35b, 35c (for example, slotted rollers) of the slider arm 35. The slider arm has inherently known detection means for locating a notch 36 in the wafer. Wafers can be aligned rotationally in a pre-determined fashion by means of this notch which has been known for a long time. Further, the contact points 35a-c can be configured rotatably with respect to the slider arm 35 whereby the particular wafer 15a can be arranged with its notch at a determined position (arrow 37). Additionally there can be provided further suitable (but not shown) detection means with which an identification means of the particular wafer, for example, a barcode of a wafer, is detected. Finally, it can also be provided that the slider arm is rotatable about a vertical axis 38 which coincides with a diameter line of a wafer arranged in the slider arm 35 (arrow 39).

By this means a wafer can be turned through 180° (known as wafer flipping). Such a change in its alignment in a wafer stack has advantages for some treatment processes.

In the loading/unloading zone it is also possible to form so-called compacted wafer stacks. Compaction is to be understood in this connection as wafers arranged adjacent to one another having a smaller spacing with respect to one another than the standardised spacing of the wafers during their transport in transport boxes. Compaction can however also be generally understood in that wafers are arranged in a new stack in which successive wafers have a smaller spacing with respect to one another than in the initial stack. Thus, in a compacted stack it is possible to provide more wafers for the same length or height of the stack. With a compaction ratio of, for example, two, three or four, the wafers have respectively a half, a third or a quarter of the original spacing with respect to one another.

With the storage device 1 shown in the embodiment according to the invention, compaction can be achieved most easily by the transfer gripper 20 arranging the wafers 15 in a storage means 25 whose successive receivers each have a smaller spacing with respect to one another compared with the grippers of the stack gripper 10. By this means, wafers from two, three or four initial stacks, for example, can be arranged over a length of an initial stack.

As shown in FIG. 2, in the storage zone 3 of the storage device, storage locations 43 (FIG. 6) are arranged in four columns 42a-d one above one another in the form of shelf-like elements on whose horizontally aligned storage surfaces 44 respectively one of the storage means 25 can be placed. Each shelf-like element can have positioning aids with which the storage means 25 can align themselves during rough pre-positioning. For example, the shelf-like elements can be provided for this purpose with several truncated-cone-shaped positioning elements 45 on which the storage means 25 can be placed. Since the storage means can be shaped with corresponding recesses on their underside, during positioning on the respective storage location 43 they slide along on the positioning elements into a pre-defined position.

A further handling device in the form of a kink-arm robot 46 shown only in part (FIG. 2) is also provided between the two pair-wise arranged columns 42a, 42b; 42c, 42d. The kink-arm robot which can be displaced in the Z direction (perpendicular to the plane of the drawing in FIG. 2) and whose kink-arm 47 can be moved horizontally in the X-Y plane, is arranged so that it is at least at approximately the same distance from each of the columns of the storage locations 43 aligned onto it. The kink-arm robot 46 is in each case positionable at the height of the shelf-like elements. An arm length of the kink-arm robot is ultimately selected so that the kink-arm robot also has access to the loading location 30. By this means it is possible to remove storage means from the loading location or place said means at the loading location using the kink-arm robot.

FIG. 6 shows one of any number of possible configurations of a storage means 25 in detail. As can be seen from this diagram, this storage means has two cross-pieces 53, 54 aligned parallel to one another in each of which are constructed slots 55, 56 for the substantially vertical accommodation of wafers 15. For reasons of clarity, FIG. 6 only shows one wafer 15 in part using dashed lines. The two cross-pieces 53, 54 are interconnected at the front faces of the storage means. Between the cross-pieces there is provided an opening 57 through which the ejector 50 (see FIGS. 2 and 5) can be passed. In addition, at almost any points in the storage means there can be provided carrying-along means by means of which the storage means can be gripped by a preferably passive gripper element for transport. In the embodiment, the carrying-along means are provided at the front faces of the storage means 25. Here they are constructed in the form of two pins each, which can each project over the stop surface. In other embodiments the carrying-along means can, for example, also be constructed as recesses on the underside of the storage means into which the gripper element of the kink-arm robot reaches through a movement parallel to the storage surface 44.

The gripper element of the handling device should be shaped so that it interacts with the carrying-along means of the storage means. The gripper element 59 of the kink-arm robot 46 shown in FIG. 6 can thus be constructed as fork-shaped. Since the distance between the two fork elements 61, 62 is larger than a length of the storage surface 44, the two fork elements can be passed vertically upwards past the front faces of the storage locations. In this case, the pins 58 enter into corresponding recesses 63 of the fork elements. As a result of the positive arrangement thereby formed, the kink-arm robot grips the respective storage means 25 and can then transport it to a predefined position, for example to the loading location 30.

In order to assemble and output a new wafer stack using this storage device according to the invention, a storage means 25 is first gripped at its storage location 43 using the kink-arm robot 46, moved to the loading location 30 and put down there. At the loading location the wafers are lifted from the storage means 25 by means of the ejector 50 so that they are accessible for the transfer gripper 20. The transfer gripper 20 removes from the storage means those wafers which are to be assembled to form a new wafer stack and output. Before the transfer gripper puts down the particular wafer in the batch gripper, it can first transfer it to the detection station where, if necessary, the notch is aligned in a pre-determined fashion and the front and back of the wafer are exchanged by rotating through 180°.

It may also be necessary to assemble a new wafer stack from wafers from two or more storage means. In this case, the kink-arm robot first brings the first storage means to the loading location 30 where a predetermined number of wafers are removed from the storage means. The wafers are then either immediately inserted by the transfer gripper 20 in a vertical position in the stack gripper or are first brought to the detection station and then to the stack gripper. After the kink-arm robot has again put down the first storage means at a storage location, it brings a second storage means to the loading location and removes from this the wafers contained therein for the new stack. This can be repeated with further storage means until the new stack is complete. The stack gripper than swivels the wafers into a horizontal position and inserts the stack into a FOUP box docked onto the housing.

As indicated schematically in FIG. 7, an air flow 70 in the storage zone 3 entering the inner chamber in the vicinity of the cover of the housing can be divided into several independent partial air flows 71. This can substantially be achieved by using flow conducting means, for example, baffles 72, 73 in the vicinity of the storage locations. The central clean-air flow introduced from above between two columns of storage locations 43 is thereby divided into two separate air flows by baffles which are inclined obliquely downwards in the direction of the side walls 74 of the housing 2. The air thus emerges from the housing at the bottom of the housing 2 near the side walls 74, for example, through a slotted bottom surface. In addition, it is hereby ensured that an air flow which has already passed by wafers and possibly contains dirt particles or other impurities does not come in contact with wafers of another storage means. So-called cross-contamination can thus be avoided.

1. A storage device for the intermediate storage of articles such as substrates, wafers, especially test wafers, and the like, provided for the production of semiconductor elements, wherein the storage device
has a housing which includes an inner chamber in which, in a loading/unloading zone, there is provided a device for introducing the articles into and removing them from the housing, for which purpose
at least one closable opening is provided on said housing through which the articles are introduced and removed, there is also provided a first handling device by means of which the articles can be handled in the loading/unloading zone,
the articles can be arranged in the inner chamber in open transportable storage means, such as magazines, for example, wherein the inner chamber has storage locations for the storage means, and the storage device also has
a transfer device for producing stacks of articles, characterised in that
a transport box for articles can be positioned with its open side on the at least one opening (6) of the housing (2), that
one or a plurality of articles are directly gripped by means of the first handling device and can be introduced into the inner chamber, that
the articles are inserted in one of the plurality of storage means (25) that are already arranged within the inner chamber, that
the storage means (25) can be arranged in storage locations (43) of the inner chamber by means of a second handling device,
and that the transfer device is also provided within the inner chamber with which one or a plurality of articles can be withdrawn from at least one storage means (25) and inserted in a receiver arranged in the inner chamber to assemble a stack of articles.

2. Storage device according to claim 1, characterised in that individual storage means (25) each have a plurality of storage locations for respectively one article.

3. Storage device according to one or both of the preceding claims, characterised in that the storage means (25) have storage locations for wafers (15, 15a) in which the wafers (15, 15a) can be arranged in a substantially vertical alignment at the storage locations.

4. Storage device according to one or several of the preceding claims, characterised in that the storage means (25) are constructed in the form of cassettes in which slots form storage locations for wafers (15, 15a).

5. Storage device according to one or several of the preceding claims, characterised in that the storage means (25) have elements with which they can be gripped during a displacement movement of the handling device by said device.

6. Storage device according to one or several of the preceding claims, characterised by a stack gripper (10) provided with a number of grippers by means of which a complete stack of articles can be withdrawn from the transport box.

7. Storage device according to claim 6, characterised in that in the storage means (25) the distance between neighbouring storage locations for articles is smaller than the distance between neighbouring grippers of the stack gripper (10).

8. Storage device according to one or several of the preceding claims, characterised by a transfer gripper (20) with which, in the loading/unloading zone (4) of the inner chamber, at least one article respectively is gripped from a stack introduced into the storage device and can be inserted in a storage means (25) arranged at a loading location (30).

9. Storage device according to one or several of the preceding claims, characterised by a detection station in which at least one article can be positioned, the detection station is provided with a rotation means with which an article can be rotated by 180° with reference to an axis running parallel to the surface of the article.

10. Storage device according to one or several of the preceding claims, characterised by a detection station in which at least one article can be arranged and at which contact points for articles are rotatable whereby the article can be rotated about an orthogonal to a surface of the substrate.

11. Storage device according to one or several of the preceding claims, characterised by a flow conducting means which guides a partial flow of a clean-room air flow so that it flows through only a few, but at the most four, preferably substantially only one, storage means.

12. Method for constructing a substrate stack from at least one initial stack of substrates where substrates are supplied in a transport box of a storage device, the substrates are introduced into an inner chamber of a housing of the storage device and stored intermediately in the inner chamber in storage means as initial stacks, substrates are withdrawn from at least one storage means by means of a handling device and assembled to form a substrate sack, characterised in that the substrates are introduced into the inner chamber without the transport box (8), the substrates are arranged there in the at least one storage means (25), the storage means can be deposited for intermediate storage at a storage location (43) of the inner chamber and the at least one storage means (25) together with the wafers arranged therein is transported from the storage location (43) of the respective storage means (25) to a loading location (30) of the inner chamber, at which a substrate stack can be assembled by withdrawing substrates from one or a plurality of storage means (25).

13. Use of a storage device according to one or several of the preceding claims 1 to 11, characterised in that it is used for open intermediate storage of test wafers.
